(19) United States
(12) Patent Application Publication
(10) Pub. No.: US 2015/0109025 A1
(43) Pub. Date: Apr. 23, 2015

(54) AREA SAVING IN LATCH ARRAYS

(71) Applicant: Qualcomm Incorporated, San Diego, CA (US)

(72) Inventors: Saravanan MARIMUTHU, Bangalore (IN); Sakthivel PACKIRISAMY, Bangalore (IN); Vijayalakshmi RANGANNA, Bangalore (IN)

(73) Assignee: Qualcomm Incorporated, San Diego, CA (US)

(21) Appl. No.: 14/057,782

(22) Filed: Oct. 18, 2013

(51) Int. Cl. H03K 19/0948; H01L 23/532; H03K 19/094; H01L 27/092

(52) U.S. Cl. CPC H03K 19/0948; H01L 27/092; H01L 23/53271; H03K 19/09425
USPC 326/58; 257/369

(57) ABSTRACT

A CMOS device includes a PMOS transistor and an NMOS transistor. The CMOS device further includes a poly interconnect connecting together a drain of the PMOS transistor and a drain of the NMOS transistor. The poly interconnect may be located on an edge of a standard cell including the device. The CMOS device may further include a first interconnect on an MD layer connecting the drain of the PMOS transistor to the poly interconnect, and a second interconnect on the MD layer connecting the drain of the NMOS transistor to the poly interconnect. The PMOS transistor and the NMOS transistor may operate as a CMOS inverter. The CMOS device may be a tristate inverter, and specifically, a tristate inverter within a latch array.

### BACKGROUND

1. Field

The present disclosure relates generally to a layout construction, and more particularly, to a latch array with a reduced layout area.

2. Background

Latch arrays are important circuit elements. Latch arrays (also may be referred to as register arrays) may be operated as a register file in a central processing unit (CPU). Reducing a chip area of a latch array may be advantageous. As such, a latch array with a reduced chip area is needed.

### SUMMARY

In an aspect of the disclosure, a complementary metal oxide semiconductor (CMOS) device is provided. The CMOS device includes a p-type metal oxide semiconductor (PMOS) transistor and an n-type metal oxide semiconductor (NMOS) transistor. The CMOS device further includes a poly interconnect connecting together a drain of the PMOS transistor and a drain of the NMOS transistor. The poly interconnect may be located on an edge of a standard cell including the device. The PMOS transistor and the NMOS transistor may operate as a CMOS inverter. The CMOS device may be a tristate inverter, and specifically, a tristate inverter within a latch array.

### BRIEF DESCRIPTION OF THE DRAWINGS

FIG. 1 is a diagram illustrating a latch array.

FIG. 2 is a circuit diagram for a tristate inverter.

FIG. 3 is a diagram for illustrating a first exemplary layout of a tristate inverter.

FIG. 4 is a first diagram for illustrating a second exemplary layout of a tristate inverter.

FIG. 5 is a second diagram for illustrating the second exemplary layout of a tristate inverter.

FIG. 6 is a diagram illustrating a side profile of the interconnects between a poly interconnect and a drain.

FIG. 7 is a diagram for illustrating a third exemplary layout of a tristate inverter.

FIG. 8 is a flow chart of a method of operating a CMOS device.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts. Apparatuses and methods will be described in the following detailed description and may be illustrated in the accompanying drawings by various blocks, modules, components, circuits, steps, processes, algorithms, elements, etc.

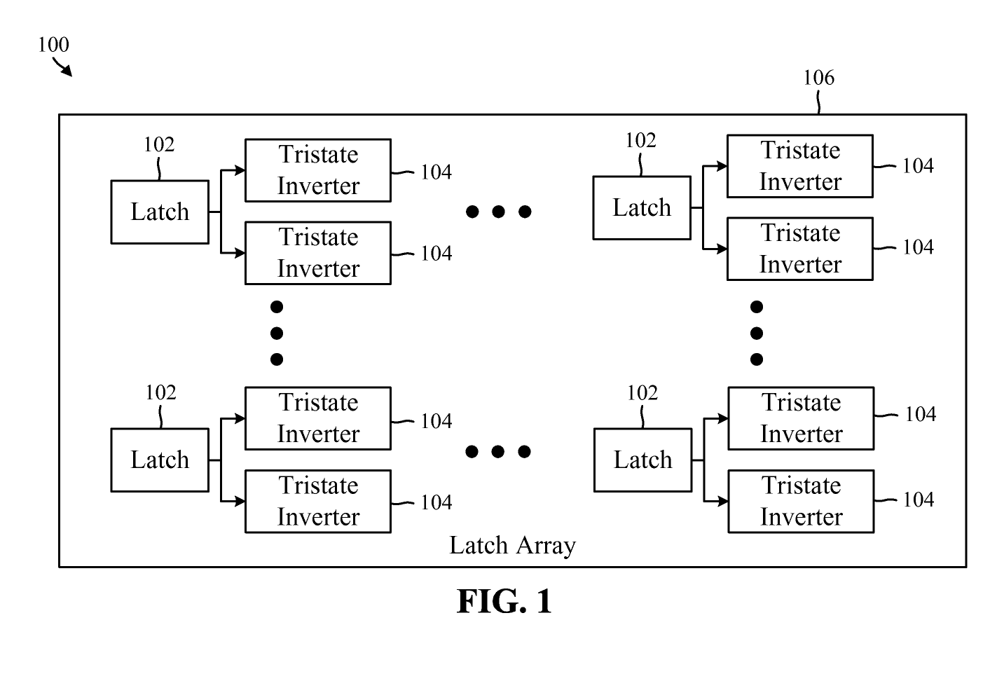

FIG. 1 is a diagram 100 illustrating a latch array 106. The latch array 106 includes a plurality of latches 102 and tristate inverters 104. Each of the latches 102 may be followed by x tristate inverters 104 for providing x read ports for reading the bit stored in each of the latches 102. In the example of FIG. 1, x=2, as each latch 102 is followed by two tristate inverters 104 for providing two read ports for reading the bit stored in each of the latches 102. As discussed infra, a chip area of the standard cell tristate inverters 104 may be reduced, thus reducing a chip area of the latch array 106.

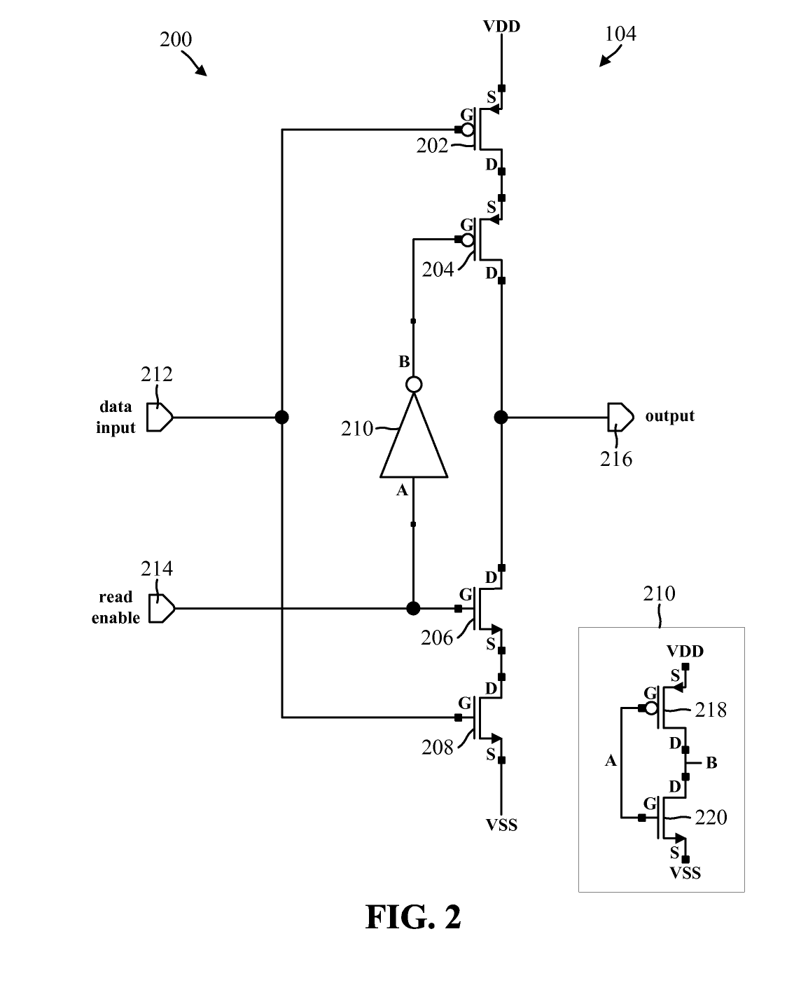

FIG. 2 is a circuit diagram 200 for a tristate inverter 104. The tristate inverter 104 may also be referred to as a multiplexer. The tristate inverter 104 includes a PMOS transistor 202, a PMOS transistor 204, an NMOS transistor 206, and an NMOS transistor 208 connected in series. The PMOS transistor 202 has a source connected to a voltage VDD, a gate connected to a data input 212, and a drain connected to a source of the PMOS transistor 204. The PMOS transistor 204 has a source connected to the drain of the PMOS transistor 202, a gate connected to an output B of an inverter 210, and a drain connected to a drain of the NMOS transistor 206 and an output 216. The NMOS transistor 206 has a drain connected to the drain of the PMOS transistor 204 and the output 216, a gate connected to an enable input 214 and an input A of the inverter 210, and a source connected to a drain of the NMOS transistor 208. The NMOS transistor 208 has a drain connected to the source of the NMOS transistor 206, a gate connected to the data input 212, and a source connected to a voltage VSS. The inverter 210 includes a PMOS transistor 218 connected in series with an NMOS transistor 220. The PMOS transistor 218 has a source connected to the voltage VDD and a drain connected to a drain of the NMOS transistor 220. A source of the NMOS transistor 220 is connected to the voltage VSS. Gates of the PMOS transistor 218 and the NMOS transistor 220 are connected together. A latch output is coupled to the data input 212. The tristate inverter 104 outputs at the output 216 the inverse of the latch output when the enable input 214 is enabled with a high voltage.

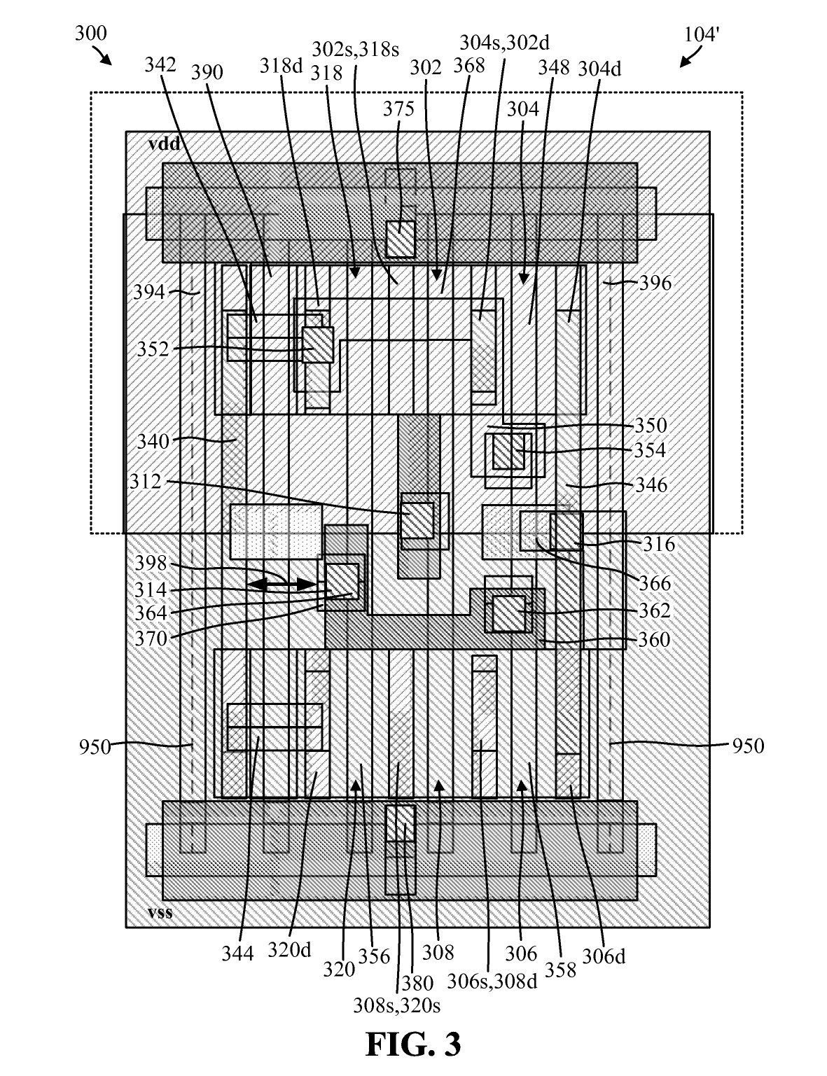

FIG. 3 is a diagram 300 for illustrating a first exemplary layout of a tristate inverter 104′. The tristate inverter 104′ is a CMOS device that includes a PMOS transistor 318 and an NMOS transistor 320. The PMOS transistor 318 corresponds to the PMOS transistor 218 and the NMOS transistor 320 corresponds to the NMOS transistor 220. A drain 318d of the PMOS transistor 318 is connected to a drain 320d of the NMOS transistor 320 by an interconnect 340 on a metal diffusion (MD) layer, an interconnect 342 on the MD layer, and an interconnect 344 on the MD layer. The interconnect 342 connects the drain 318d to the interconnect 340, and the interconnect 344 connects the drain 320d to the interconnect 340. The tristate inverter 104′ further includes a second PMOS transistor 304 and a second NMOS transistor 306. The second PMOS transistor 304 corresponds to the PMOS transistor 204 and the second NMOS transistor 306 corresponds to the NMOS transistor 206. An interconnect 346 on the MD layer connects a drain 304d of the second PMOS transistor 304 to a drain 306d of the second NMOS transistor 306. An output 316 is connected to the interconnect 346. The output 316 corresponds to the output 216. A poly interconnect 348 is connected to a gate of the second PMOS transistor 304. An interconnect 350 on an interconnect level (e.g., a first metal layer Ml) connects a drain 318d of the PMOS transistor 318 to the poly interconnect 348. The interconnect 350 is connected to the drain 318d at via 352 and is connected to the poly interconnect 348 at via 354. The interconnect 350 may alternatively connect a drain 320d of the NMOS transistor 320 to the poly interconnect 348. A poly interconnect 356 connects a gate of the PMOS transistor 318 to a gate of the NMOS transistor 320. An enable input 314 is connected to the poly interconnect 356. The enable input 314 corresponds to the enable input 214. A poly interconnect 358 is connected to a gate of the second NMOS transistor 306. The poly interconnects 348, 358 may be formed from one poly interconnect that is disconnected at 366 and split into the two poly interconnects 348, 358. An interconnect 360 on an interconnect level (e.g., a first metal layer Ml) connects the poly interconnect 356 to the poly interconnect 358. The interconnect 360 is connected to the poly interconnect 358 at via 362 and to the poly interconnect 356 at via 364. Specifically, the interconnect 360 is connected to the poly interconnect 356 through the via 364 and an interconnect 370 on a metal poly (MP) layer that is connected directly to the poly interconnect 356. The tristate inverter 104′ further includes a third PMOS transistor 302 and a third NMOS transistor 308. The third PMOS transistor 302 corresponds to the PMOS transistor 202 and the third NMOS transistor 308 corresponds to the NMOS transistor 208. A source 304s of the second PMOS transistor 304 is a drain 302d of the third PMOS transistor 302. A source 306s of the second NMOS transistor 306 is a drain 308d of the third NMOS transistor 308. A source 302s of the third PMOS transistor 302 is also a source 318s of the PMOS transistor 318. The sources 302s, 318s are connected to VDD at via 375. A source 308s of the third NMOS transistor 308 is also a source 320s of the NMOS transistor 320. The sources 308s, 320s are connected to VSS at via 380. A poly interconnect 368 connects a gate of the third PMOS transistor 302 to a gate of the third NMOS transistor 308. A data input 312 is connected to the poly interconnect 368. The data input 312 corresponds to the data input 212.

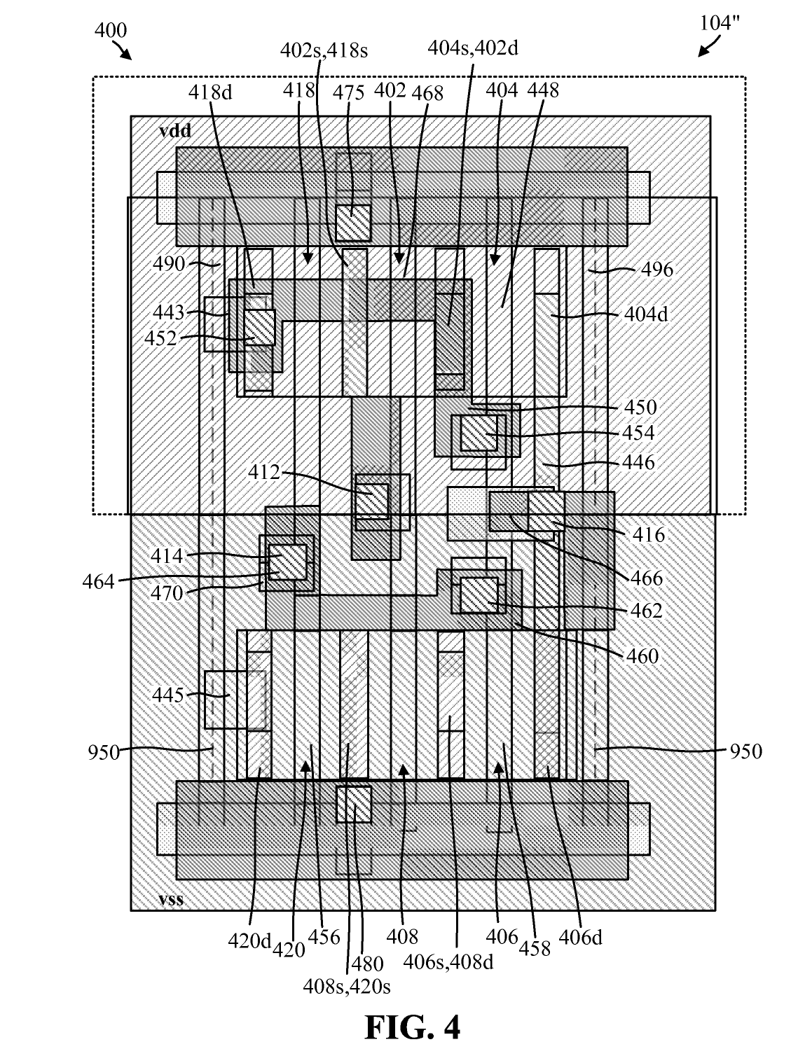

As shown in FIG. 3, the tristate inverter 104′ has a five-grid layout, as the tristate inverter includes five poly interconnects (gates & dummy gates) with the same pitch (distance between each of the poly interconnects) extending lengthwise (poly interconnects 390, 356, 368, 358 and two half poly interconnects 394, 396 on the edges of the standard cell; the dotted lines 950 are the edges of the standard cell). The poly interconnect/dummy gate 390 is not utilized to form a connection and is included in order to add one grid so that the spacing 398 between the MD layer interconnect 340 and the MP layer interconnect 370 satisfies requisite design rule check (DRC) spacing for the process technology (e.g., 20 nm system-on-chip (SoC) process technology). Without proper spacing 398, the MD layer interconnect 340 and the MP layer interconnect 370 could potentially be shorted together. Including the unutilized poly interconnect/dummy gate 390 increases a size of the tristate inverter 104′. A tristate inverter 104″ with a four-grid layout that utilizes the poly interconnect/dummy gate 390 is provided infra with respect to FIG. 4.

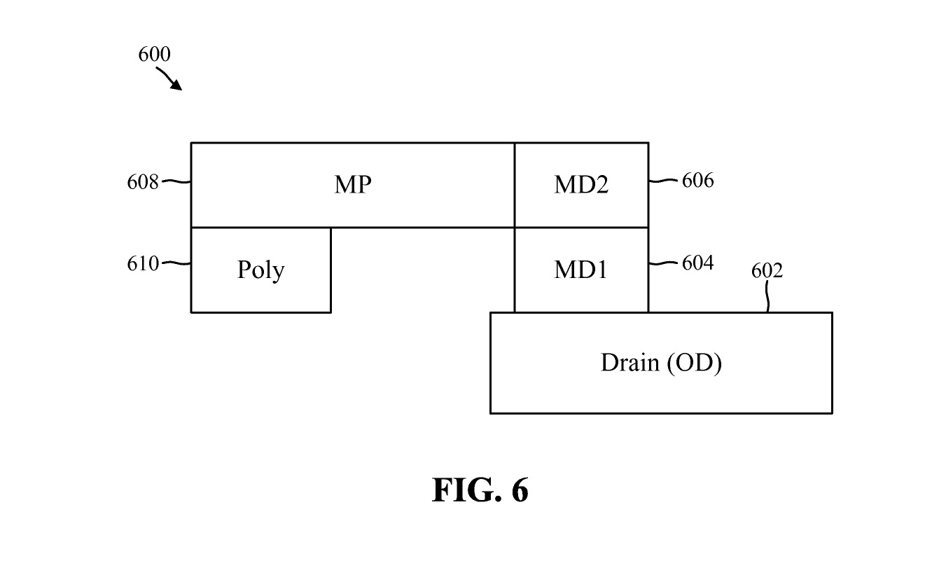

FIG. 4 is a first diagram 400 for illustrating a second exemplary layout of a tristate inverter 104″. The tristate inverter 104″ is a CMOS device that includes a PMOS transistor 418 and an NMOS transistor 420. The PMOS transistor 418 corresponds to the PMOS transistor 218 and the NMOS transistor 420 corresponds to the NMOS transistor 220. A drain 418d of the PMOS transistor 418 is connected to a drain 420d of the NMOS transistor 420 by a poly interconnect 490. The drain 418d of the PMOS transistor 418 is connected to the poly interconnect 490 through an MD layer interconnect attached to the drain 418d and an MP layer interconnect 443 connecting the poly interconnect 490 to the MD layer interconnect (shown in FIG. 6). The drain 420d of the NMOS transistor 420 is connected to the poly interconnect 490 through an MD layer interconnect attached to the drain 420d and an MP layer interconnect 445 connecting the poly interconnect 490 to the MD layer interconnect (shown in FIG. 6). The tristate inverter 104″ further includes a second PMOS transistor 404 and a second NMOS transistor 406. The second PMOS transistor 404 corresponds to the PMOS transistor 204 and the second NMOS transistor 406 corresponds to the NMOS transistor 206. An interconnect 446 on the MD layer connects a drain 404d of the second PMOS transistor 404 to a drain 406d of the second NMOS transistor 406. An output 416 is connected to the interconnect 446. The output 416 corresponds to the output 216. A second poly interconnect 448 is connected to a gate of the second PMOS transistor 404. An interconnect 450 on an interconnect level (e.g., a first metal layer Ml) connects a drain 418d of the PMOS transistor 418 to the second poly interconnect 448. The interconnect 450 is connected to the drain 418d at via 452 and is connected to the second poly interconnect 448 at via 454. The interconnect 450 may alternatively connect a drain 420d of the NMOS transistor 420 to the second poly interconnect 448. A third poly interconnect 456 connects a gate of the PMOS transistor 418 to a gate of the NMOS transistor 420. An enable input 414 is connected to the third poly interconnect 456. The enable input 414 corresponds to the enable input 214. A fourth poly interconnect 458 is connected to a gate of the second NMOS transistor 406. The second poly interconnect 448 and the fourth poly interconnect 458 may be formed from one poly interconnect that is disconnected at 466 and split into the two poly interconnects 448, 458. An interconnect 460 on an interconnect level (e.g., a first metal layer Ml) connects the third poly interconnect 456 to the fourth poly interconnect 458. The interconnect 460 is connected to the fourth poly interconnect 458 at via 462 and to the third poly interconnect 456 at via 464. Specifically, the interconnect 460 is connected to the third poly interconnect 456 through the via 464 and an interconnect 470 on an MP layer that is connected directly to the third poly interconnect 456. The tristate inverter 104″ further includes a third PMOS transistor 402 and a third NMOS transistor 408. The third PMOS transistor 402 corresponds to the PMOS transistor 202 and the third NMOS transistor 408 corresponds to the NMOS transistor 208. A source 404s of the second PMOS transistor 404 is a drain 402d of the third PMOS transistor 402. A source 406s of the second NMOS transistor 406 is a drain 408d of the third NMOS transistor 408. A source 402s of the third PMOS transistor 402 is also a source 418s of the PMOS transistor 418. The sources 402s, 418s are connected to VDD at via 475. A source 408s of the third NMOS transistor 408 is also a source 420s of the NMOS transistor 420. The sources 408s, 420s are connected to VSS at via 480. A fifth poly interconnect 468 connects a gate of the third PMOS transistor 402 to a gate of the third NMOS transistor 408. A data input 412 is connected to the fifth poly interconnect 468. The data input 412 corresponds to the data input 212.

As shown in FIG. 4, the tristate inverter 104″ has a four-grid layout, as the tristate inverter includes four poly interconnects with the same pitch extending lengthwise (poly interconnects 456, 468, 458 and two half poly interconnects 490, 496 on the edges of the standard cell; the dotted lines 950 are the edges of the standard cell). The poly interconnect 490 has half of the width of the poly interconnects 456, 468, 458 within a standard cell. Even when the tristate inverter standard cell is located adjacent to another standard cell with a dummy gate (unutilized poly interconnect) so that the poly interconnect 490 has a normal poly interconnect width, the width of the poly interconnect 490 is less than the width of the MD layer interconnect 340. Because the width of the poly interconnect 490 is less than the width of the MD layer interconnect 340, the poly interconnect 490 has greater resistance than the MD layer interconnect 340 and is therefore a slower connection than the MD layer interconnect 340. The MD layer interconnect 340 and the poly interconnect 490 correspond to the connection between the drains of the PMOS transistor 218 and the NMOS transistor 220 at the output B of the inverter 210. Slowing down the signal between the drains of the transistors 218, 220 does not significantly degrade the performance of the tristate inverter 104″. Accordingly, connecting the drains 418d, 420d of the transistors 418, 420 with the poly interconnect 490 rather than the MD layer interconnect 340 provides area savings for a tristate inverter standard cell without significantly degrading the performance of the tristate inverter. When the tristate inverter 104″ is used in a 16×128 latch array with two read ports, 256 grids are reduced in the latch array, providing up to a 10.9% area savings.

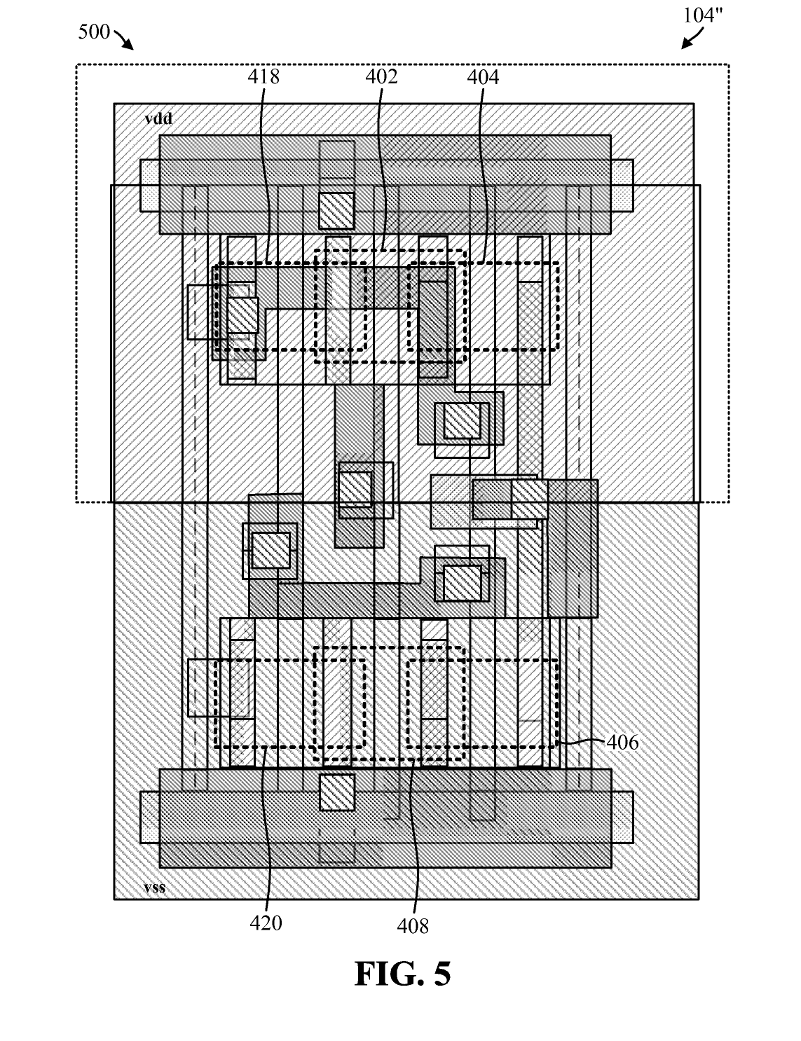

FIG. 5 is a second diagram 500 for illustrating the second exemplary layout of a tristate inverter 104″. As shown in FIG. 5, rectangular dotted boxes outline the PMOS transistors 418, 402, 404 and the NMOS transistors 420, 408, 406. The PMOS transistors 418, 402, 404 correspond to the PMOS transistors 218, 202, 204, respectively, and the NMOS transistors 420, 408, 406 correspond to the NMOS transistors 220, 208, 206, respectively.

FIG. 6 is a diagram 600 illustrating a side profile of the interconnects between a poly interconnect and a drain. The diagram 600 specifically illustrates the interconnection of the drain 418d of the PMOS transistor 418 to the poly interconnect 490 and the drain 420d of the NMOS transistor 420 to the poly interconnect 490. The poly interconnect 610 may be a metal interconnect, such as in the 20 nm process technology. However, in other process technologies, the poly interconnect 610 may be entirely polysilicon or may be polysilicon with a metal top layer. A first MD layer interconnect 604 is on the drain 602 (also referred to as oxide diffusion (OD)), and a second MD layer interconnect 606 is on the first MD layer interconnect 604. The first and second MD layers 604, 606 may be referred to herein (e.g., with respect to FIGS. 3, 4, and 7) as just one MD layer. The MD layer connects directly to a drain. An MP layer interconnect 608 connects the poly interconnect 610 to the second MD layer interconnect 606. The MP layer connects directly to a poly interconnect. The MD and MP layers may be connected to a metal layer, such as the metal layer Ml, through a via.

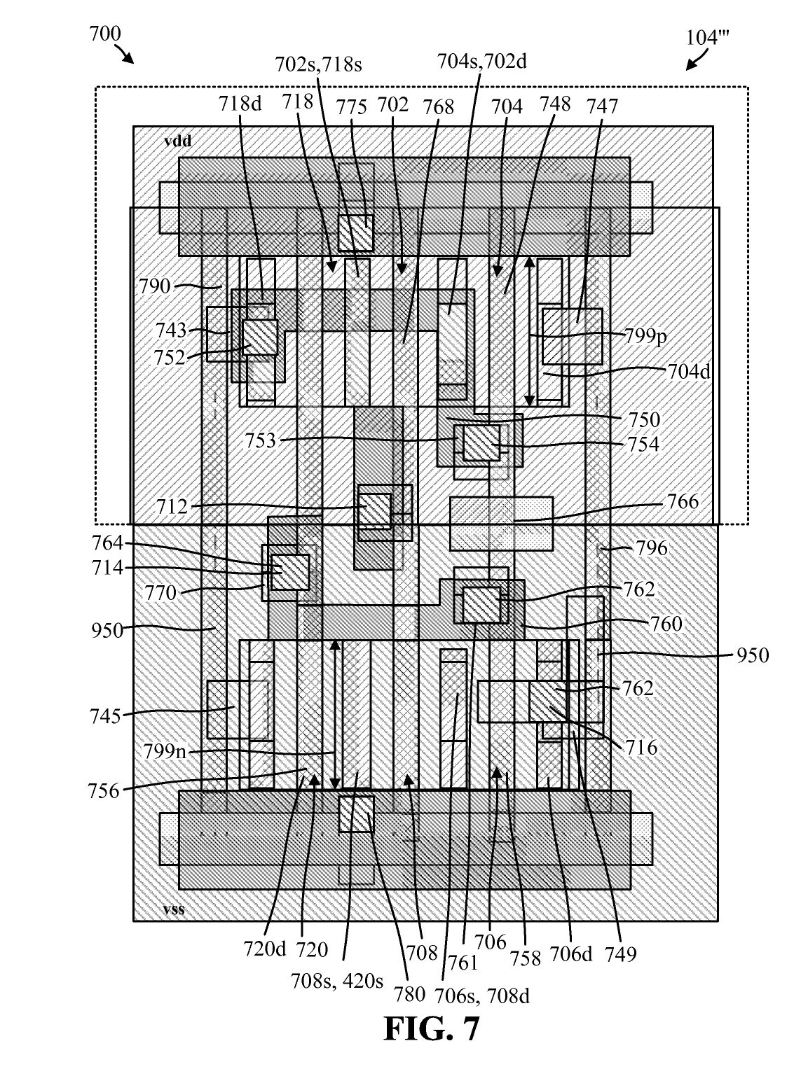

FIG. 7 is a diagram 700 for illustrating a third exemplary layout of a tristate inverter 104″′. The tristate inverter 104″′ is a CMOS device that includes a PMOS transistor 718 and an NMOS transistor 720. The PMOS transistor 718 corresponds to the PMOS transistor 218 and the NMOS transistor 720 corresponds to the NMOS transistor 220. A drain 718d of the PMOS transistor 718 is connected to a drain 720d of the NMOS transistor 720 by a poly interconnect 790. The drain 718d of the PMOS transistor 718 is connected to the poly interconnect 790 through an MD layer interconnect attached to the drain 718d and an MP layer interconnect 743 connecting the poly interconnect 790 to the MD layer interconnect (shown in FIG. 6). The drain 720d of the NMOS transistor 720 is connected to the poly interconnect 790 through an MD layer interconnect attached to the drain 720d and an MP layer interconnect 745 connecting the poly interconnect 790 to the MD layer interconnect (shown in FIG. 6). The tristate inverter 104″′ further includes a second PMOS transistor 704 and a second NMOS transistor 706. The second PMOS transistor 704 corresponds to the PMOS transistor 204 and the second NMOS transistor 706 corresponds to the NMOS transistor 206. A second poly interconnect 748 is connected to a gate of the second PMOS transistor 704. An interconnect 750 on an interconnect level (e.g., a first metal layer Ml) connects a drain 718d of the PMOS transistor 718 to the second poly interconnect 748. The interconnect 750 is connected to the drain 718d at via 752 and is connected to the second poly interconnect 748 at via 754. The interconnect 750 may alternatively connect a drain 720d of the NMOS transistor 720 to the second poly interconnect 748. A third poly interconnect 756 connects a gate of the PMOS transistor 718 to a gate of the NMOS transistor 720. An enable input 714 is connected to the third poly interconnect 756. The enable input 714 corresponds to the enable input 214. A fourth poly interconnect 758 is connected to a gate of the second NMOS transistor 706. The second poly interconnect 748 and the fourth poly interconnect 758 may be formed from one poly interconnect that is disconnected at 766 and split into the two poly interconnects 748, 758. An interconnect 760 on an interconnect level (e.g., a first metal layer Ml) connects the third poly interconnect 756 to the fourth poly interconnect 758. The interconnect 760 is connected to the fourth poly interconnect 758 at via 762 and to the third poly interconnect 756 at via 764. Specifically, the interconnect 760 is connected to the third poly interconnect 756 through the via 764 and an interconnect 770 on an MP layer that is connected directly to the third poly interconnect 756. The tristate inverter 104″′ further includes a third PMOS transistor 702 and a third NMOS transistor 708. The third PMOS transistor 702 corresponds to the PMOS transistor 202 and the third NMOS transistor 708 corresponds to the NMOS transistor 208. A source 704s of the second PMOS transistor 704 is a drain 702d of the third PMOS transistor 702. A source 706s of the second NMOS transistor 706 is a drain 708d of the third NMOS transistor 708. A source 702s of the third PMOS transistor 702 is also a source 718s of the PMOS transistor 718. The sources 702s, 718s are connected to VDD at via 775. A source 708s of the third NMOS transistor 708 is also a source 720s of the NMOS transistor 720. The sources 708s, 720s are connected to VSS at via 780. A fifth poly interconnect 768 connects a gate of the third PMOS transistor 702 to a gate of the third NMOS transistor 708. A data input 712 is connected to the fifth poly interconnect 768. The data input 712 corresponds to the data input 212.

As shown in FIG. 7, a sixth poly interconnect 796 connects a drain 704d of the second PMOS transistor 704 to a drain 706d of the second NMOS transistor 706. The drain 704d of the PMOS transistor 704 is connected to the sixth poly interconnect 796 through an MD layer interconnect attached to the drain 704d and an MP layer interconnect 747 connecting the sixth poly interconnect 796 to the MD layer interconnect (see FIG. 6). The drain 706d of the NMOS transistor 706 is connected to the sixth poly interconnect 796 through an MD layer interconnect attached to the drain 706d and an MP layer interconnect 749 connecting the sixth poly interconnect 796 to the MD layer interconnect (see FIG. 6). An output 716 is connected to the sixth poly interconnect 796. The output 716 corresponds to the output 216.

The sixth poly interconnect 796 is utilized to connect the drains 704d, 706d rather than the MD layer interconnect 446. By removing the MD layer interconnect 446, the MP layer interconnect 753 between the second poly interconnect 748 and the via 754 may be shifted/moved in order to increase an OD width 799p of the PMOS transistors 718, 702, 704. Further, by removing the MD layer interconnect 446, the MP layer interconnect 761 between the fourth poly interconnect 758 and the via 762 may be shifted/moved in order to increase an OD width 799n of the NMOS transistors 720, 708, 706. Specifically, the MP layer interconnects 753, 761 may be staggered with respect to each other (not shown in FIG. 7) so that they are closer to each other without violating requisite MP layer DRC spacing for the process technology. The tristate inverter 104″′ has a four-grid layout, as the tristate inverter includes four poly interconnects with the same pitch extending lengthwise (poly interconnects 756, 768, 758 and two half poly interconnects 790, 796 on the edges of the standard cell; the dotted lines 950 are the edges of the standard cell). The poly interconnect 796 has half of the width of the poly interconnects 756, 768, 758 within a standard cell. Even when the tristate inverter standard cell is located adjacent to another standard cell with a dummy gate (unutilized poly interconnect) so that the poly interconnect 796 has a normal poly interconnect width, the width of the poly interconnect 796 is less than the width of the MD layer interconnect 446. Because the width of the poly interconnect 796 is less than the width of the MD layer interconnect 446, the poly interconnect 796 has greater resistance than the MD layer interconnect 446 and is therefore a slower connection than the MD layer interconnect 446. The MD layer interconnect 446 and the poly interconnect 796 correspond to the connection between the drains of the PMOS transistor 204 and the NMOS transistor 206 at the output of the tristate inverter 104″′. Slowing down the signal between the drains of the transistors 204, 206 does not significantly degrade the performance of the tristate inverter 104″′. Accordingly, connecting the drains 704d, 706d of the transistors 704, 706 with the poly interconnect 796 rather than the MD layer interconnect 446 provides a drive strength increase (due to the increased OD width) for a tristate inverter 104″′ without significantly degrading the performance of the tristate inverter.

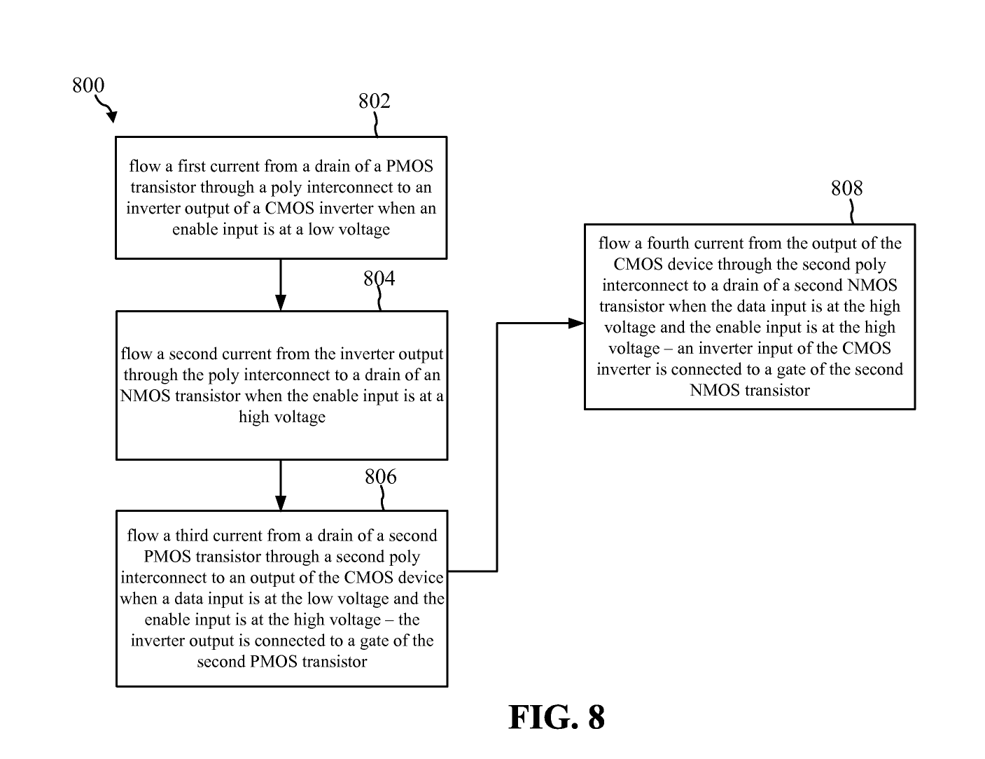

FIG. 8 is a flow chart 800 of a method of operating a CMOS device. In step 802, a first current flows from a drain of a PMOS transistor through a poly interconnect to an inverter output of a CMOS inverter when an enable input is at a low voltage. In step 804, a second current flows from the inverter output through the poly interconnect to a drain of an NMOS transistor when the enable input is at a high voltage. For example, referring to FIGS. 2, 4, and 7, a first current flows from a drain 418d, 718d of a PMOS transistor 218, 418, 718 through a poly interconnect 490, 790 to an inverter output B of a CMOS inverter 210 when an enable input 214, 414, 714 is at a low voltage. Further, a second current flows from the inverter output B through the poly interconnect 490, 790 to a drain 420d, 720d of an NMOS transistor 220, 420, 720 when the enable input 214, 414, 714 is at a high voltage. As discussed supra, the drain of the PMOS transistor 218, 418, 718 is coupled to the drain of the NMOS transistor 220, 420, 720 by the poly interconnect.

In step 806, a third current flows from a drain of a second PMOS transistor through a second poly interconnect to an output of the CMOS device when a data input is at the low voltage and the enable input is at the high voltage. The inverter output is connected to a gate of the second PMOS transistor. In step 808, a fourth current flows from the output of the CMOS device through the second poly interconnect to a drain of a second NMOS transistor when the data input is at the high voltage and the enable input is at the high voltage. An inverter input of the CMOS inverter is connected to a gate of the second NMOS transistor. For example, referring to FIGS. 2 and 7, a third current flows from a drain 704d of a second PMOS transistor 204, 704 through a second poly interconnect 796 to an output 216, 716 of the CMOS device when a data input 212, 712 is at the low voltage and the enable input 214, 714 is at the high voltage. The inverter output B is connected to a gate of the second PMOS transistor 204, 704. A fourth current flows from the output 216, 716 of the CMOS device through the second poly interconnect 796 to a drain 706d of a second NMOS transistor 206, 706 when the data input 212, 712 is at the high voltage and the enable input 214, 714 is at the high voltage. An inverter input A of the CMOS inverter 210 is connected to a gate of the second NMOS transistor 206, 706. The poly interconnect and the second poly interconnect may be located on edges of a standard cell including the device. The PMOS transistor and the NMOS transistor may operate as the CMOS inverter. The CMOS device may be a tristate inverter.

In one configuration, a CMOS device may include means for flowing a first current from a drain of a PMOS transistor through a poly interconnect to an inverter output of a CMOS inverter when an enable input is at a low voltage. The CMOS device may further include means for flowing a second current from the inverter output through the poly interconnect to a drain of an NMOS transistor when the enable input is at a high voltage. The means for flowing the first current and the means for flowing the second current may be the PMOS and NMOS transistors, the inverter output, the enable input, and the poly interconnect (e.g., the poly interconnects 490, 790) that interconnects the drains of the PMOS transistor (e.g., the PMOS transistors 418, 718) and the NMOS transistor (e.g., the NMOS transistors 420, 720). The CMOS device may further include means for flowing a third current from a drain of a second PMOS transistor through a second poly interconnect to an output of the CMOS device when a data input is at the low voltage and the enable input is at the high voltage. The inverter output is connected to a gate of the second PMOS transistor. The CMOS device may further include means for flowing a fourth current from the output of the CMOS device through the second poly interconnect to a drain of a second NMOS transistor when the data input is at the high voltage and the enable input is at the high voltage. An inverter input of the CMOS inverter is connected to a gate of the second NMOS transistor. The means for flowing the third current and the means for flowing the fourth current may be the second PMOS transistor and the second NMOS transistor, the output of the CMOS device, the enable input, the data input, and the second poly interconnect (e.g., the poly interconnect 796) that interconnects the drains of the second PMOS transistor (e.g., the PMOS transistor 704) and the second NMOS transistor (e.g., the NMOS transistor 706).

It is understood that the specific order or hierarchy of steps in the processes disclosed is an illustration of exemplary approaches. Based upon design preferences, it is understood that the specific order or hierarchy of steps in the processes may be rearranged. Further, some steps may be combined or omitted. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” The word “exemplary” is used herein to mean “serving as an example, instance, or illustration.” Any aspect described herein as “exemplary” is not necessarily to be construed as preferred or advantageous over other aspects.” Unless specifically stated otherwise, the term “some” refers to one or more. Combinations such as “at least one of A, B, or C,” “at least one of A, B, and C,” and “A, B, C, or any combination thereof” include any combination of A, B, and/or C, and may include multiples of A, multiples of B, or multiples of C. Specifically, combinations such as “at least one of A, B, or C,” “at least one of A, B, and C,” and “A, B, C, or any combination thereof” may be A only, B only, C only, A and B, A and C, B and C, or A and B and C, where any such combinations may contain one or more member or members of A, B, or C. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

What is claimed is:

1. A complementary metal oxide semiconductor (CMOS) device comprising:
a p-type metal oxide semiconductor (PMOS) transistor and an n-type metal oxide semiconductor (NMOS) transistor; and
a poly interconnect connecting together a drain of the PMOS transistor and a drain of the NMOS transistor.

2. The device of claim 1, wherein the poly interconnect is a located on an edge of a standard cell including the device.

3. The device of claim 1, further comprising:
a first interconnect on a metal poly (MP) layer coupling the drain of the PMOS transistor to the poly interconnect; and
a second interconnect on the MP layer coupling the drain of the NMOS transistor to the poly interconnect.

4. The device of claim 1, further comprising:
a second PMOS transistor and a second NMOS transistor;
a first interconnect connecting a drain of the second PMOS transistor to a drain of the second NMOS transistor;
a second poly interconnect connected to a gate of the second PMOS transistor;
a second interconnect on an interconnect level connecting at least one of a drain of the PMOS transistor or a drain of the NMOS transistor to the second poly interconnect;
a third poly interconnect connecting a gate of the PMOS transistor to a gate of the NMOS transistor;
a fourth poly interconnect connected to a gate of the second NMOS transistor; and
a third interconnect on the interconnect level connecting the third poly interconnect to the fourth poly interconnect.

5. The device of claim 4, wherein the second interconnect connects the drain of the PMOS transistor to the second poly interconnect.

6. The device of claim 4, wherein the second poly interconnect and the fourth poly interconnect are formed from one poly interconnect that is disconnected and split into two poly interconnects.

7. The device of claim 4, wherein an enable input is connected to the third poly interconnect and an output is connected to the first interconnect.

8. The device of claim 4, further comprising:
a third PMOS transistor and a third NMOS transistor, a source of the second PMOS transistor being a drain of the third PMOS transistor, a source of the second NMOS transistor being a drain of the third NMOS transistor; and
a fifth poly interconnect connecting a gate of the third PMOS transistor to a gate of the third NMOS transistor.

9. The device of claim 8, wherein a data input is connected to the fifth poly interconnect.

10. The device of claim 8, wherein the first interconnect is on a metal diffusion (MD) layer.

11. The device of claim 8, wherein the first interconnect is a sixth poly interconnect and is located on an edge of a standard cell including the device.

12. The device of claim 1, wherein the PMOS transistor and the NMOS transistor operate as a CMOS inverter.

13. The device of claim 1, wherein the CMOS device is a tristate inverter.

14. A method of operating a complementary metal oxide semiconductor (CMOS) device comprising:
flowing a first current from a drain of a p-type metal oxide semiconductor (PMOS) transistor through a poly interconnect to an inverter output of a CMOS inverter when an enable input is at a low voltage; and
flowing a second current from the inverter output through the poly interconnect to a drain of an n-type metal oxide semiconductor (NMOS) transistor when the enable input is at a high voltage.

15. The method of claim 14, wherein the drain of the PMOS transistor is coupled to the drain of the NMOS transistor by the poly interconnect.

16. The method of claim 14, further comprising:
flowing a third current from a drain of a second PMOS transistor through a second poly interconnect to an output of the CMOS device when a data input is at the low voltage and the enable input is at the high voltage, the inverter output being connected to a gate of the second PMOS transistor; and
flowing a fourth current from the output of the CMOS device through the second poly interconnect to a drain of a second NMOS transistor when the data input is at the high voltage and the enable input is at the high voltage, an inverter input of the CMOS inverter being connected to a gate of the second NMOS transistor.

17. The method of claim 16, wherein the poly interconnect and the second poly interconnect are located on edges of a standard cell including the device.

18. The method of claim 14, wherein the PMOS transistor and the NMOS transistor operate as the CMOS inverter.

19. The method of claim 14, wherein the CMOS device is a tristate inverter.

20. A complementary metal oxide semiconductor (CMOS) device comprising:
means for flowing a first current from a drain of a p-type metal oxide semiconductor (PMOS) transistor through a poly interconnect to an inverter output of a CMOS inverter when an enable input is at a low voltage; and
means for flowing a second current from the inverter output through the poly interconnect to a drain of an n-type metal oxide semiconductor (NMOS) transistor when the enable input is at a high voltage.
